(19) United States
(12) Patent Application Publication
(10) Pub. No.: US 2026/0372097 A1
(43) Pub. Date: Nov. 19, 2026

(54) PACKAGE STRUCTURE INCLUDING RING STRUCTURE AND METHODS OF FORMING THE SAME

(71) Applicant: Taiwan Semiconductor Manufacturing Company Limited, Hsinchu (TW)

(72) Inventors: Li-Ling Liao, Hsinchu (TW); Ming-Chih Yew, Hsinchu (TW); Kuo-Chin Chang, Chiayi City (TW); Kathy Wei Yan, Hsinchu (TW); Chen-Shien Chen, Zhubei City (TW)

(21) Appl. No.: 19/209,872

(22) Filed: May 16, 2025

(51) Int. Cl. H10W 42/00; H10W 40/10

(52) U.S. Cl. CPC H10W 42/121; H10W 40/10

(57) ABSTRACT

A package structure may include a package substrate, a semiconductor die module on the package substrate, and a ring structure on the package substrate around the semiconductor die module, including a lower ring including a lower ring first portion having a first width and a lower ring second portion having a second width greater than the first width, and an upper ring attached to the lower ring second portion.

### BACKGROUND

A package structure (e.g., semiconductor package) may house and protect one or more semiconductor dies (e.g., chips). The package structure may be subject to various stresses and strains during the manufacturing process, as well as during handling, assembly, and operation. For example, thermal cycling during the manufacturing process may cause the package structure to heat and cool. This thermal cycling and the differences in thermal coefficients of expansion for the various materials used in the package structure may cause stress and strain on the package structure. These stresses may cause the package structure to warp and deform, which may result in various types of failures, such as cracking or delamination of the package materials, or damage to the semiconductor dies.

The package structure may include a ring structure to provide mechanical support and increase the overall structural integrity of the package structure. The ring structure may be made of a rigid material, such as metal or ceramic. The ring structure may be placed around a periphery of the semiconductor dies. It may be designed to provide additional mechanical support to the package, particularly at the edges where stresses are most likely to occur. The ring structure may help to distribute stresses evenly across the package structure, and may mitigate against deformation and damage to the package and its contents. The ring structure may thereby increase the reliability of the package structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure (e.g., organic/silicon interposer package) according to one or more embodiments.

FIG. 1B is a magnified vertical cross-sectional view of a ring structure in the package structure according to one or more embodiments.

FIG. 1C is a top-down view (e.g., plan view) of the package structure according to one or more embodiments. The vertical cross-sectional view in FIG. 1A is along the line A-A′ in FIG. 1C.

FIG. 2A is a perspective view of an intermediate structure including a metal sheet according to one or more embodiments.

FIG. 2B is a perspective view of the metal sheet including the lower ring first portion, according to one or more embodiments.

FIG. 2C is a perspective view of the metal sheet including the lower ring second portion, according to one or more embodiments.

FIG. 3A is a vertical cross-sectional view of an intermediate structure including the interposer (e.g., organic interposer) formed on a first carrier substrate (e.g., carrier wafer) according to an embodiment of the present invention.

FIG. 3B is a vertical cross-sectional view of an intermediate structure including the microbumps, according to an embodiment of the present invention.

FIG. 3C is a vertical cross-sectional view of an intermediate structure including the first semiconductor die and second semiconductor die, according to one or more embodiments.

FIG. 3D is a vertical cross-sectional view of an intermediate structure including the die module underfill layer (e.g., microbump underfill) according to one or more embodiments.

FIG. 3E is a vertical cross-sectional view of an intermediate structure including the upper molding material layer, according to one or more embodiments.

FIG. 3F illustrates a vertical cross-sectional view of an intermediate structure including a second carrier substrate, according to one or more embodiments.

FIG. 3G illustrates a vertical cross-sectional view of an intermediate structure including the interposer lower bonding pads, according to one or more embodiments.

FIG. 3H illustrates a vertical cross-sectional view of the intermediate structure after a dicing process, according to one or more embodiments.

FIG. 3I illustrates a vertical cross-sectional view of an intermediate structure in which the semiconductor die module may be mounted on the package substrate, according to one or more embodiments.

FIG. 3J illustrates a vertical cross-sectional view of an intermediate structure in which the package underfill layer may be formed on the package substrate, according to one or more embodiments.

FIG. 3K illustrates a vertical cross-sectional view of an intermediate structure including the ring structure on the package substrate, according to one or more embodiments.

FIG. 3L illustrates a vertical cross-sectional view of an intermediate structure in which a plurality of solder balls may be formed on the package substrate, according to one or more embodiments.

FIG. 4 is a flow chart illustrating a method of making the package structure according to one or more embodiments.

FIG. 5 is a vertical cross-sectional view of the package structure having a first alternative configuration according to one or more embodiments.

FIG. 6 is a vertical cross-sectional view of the package structure having a second alternative configuration according to one or more embodiments.

FIG. 7 is a top-down view of the package structure having a third alternative configuration according to one or more embodiments.

FIG. 8A is a vertical cross-sectional view of the package structure having the third alternative configuration along the line A-A′ in FIG. 7, according to one or more embodiments.

FIG. 8B is a vertical cross-sectional view of the package structure having the third alternative configuration along the line B-B′ in FIG. 7, according to one or more embodiments.

FIG. 9 is a vertical cross-sectional view of the package structure having a fourth alternative configuration according to one or more embodiments.

FIG. 10 is a vertical cross-sectional view of the package structure having a fifth alternative configuration according to one or more embodiments.

FIG. 11 is a vertical cross-sectional view of the package structure having a sixth alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A package structure may include a die module (e.g., semiconductor die module) on a package substrate. A ring structure (e.g., ring structure) may be attached to the package substrate around the die module. The ring structure may include a lower ring portion attached to the package substrate and an upper ring portion attached to the lower ring portion by an adhesive layer.

However, the package structure may experience stresses on the package structure may cause a delamination of the upper ring portion from the lower ring portion. Delamination may be caused, for example, by stresses resulting from the lower ring portion and upper ring portion having different coefficients of thermal expansion (CTE). During temperature cycling (e.g., manufacturing processes, power-up cycles), repeated expansion and contraction can cause mechanical stress, leading to delamination. Delamination may also be caused by stresses resulting from vibration or large mechanical loads, such as those experienced during transport, drop tests, or PCB assembly.

Delamination may also be caused by poor adhesion of the adhesive layer. Poor adhesion may be caused, for example, by surface contamination (e.g., oxidation, residues, moisture) reducing adhesion strength. Poor adhesion may also be caused by insufficient curing of the adhesive layer, improper application of the adhesive layer or air bubbles formed in the adhesive layer during assembly.

Delamination of the upper ring portion from the lower ring portion may cause inhibit the performance of the package structure. In particular, delamination may cause package warpage (deformation), solder joint reliability and overall mechanical integrity issues in the package structure. Package warpage caused by delamination may also al-ter wire bond or flip-chip interconnect integrity, potentially causing signal integrity issues or open circuits.

At least one embodiment of the present disclosure may include a package structure including a package substrate, a semiconductor die module on the package substrate. The semiconductor die module may include an interposer (Si interposer or redistribution layer (RDL)), and one or more semiconductor dies (e.g., semiconductor chips) on the interposer. The semiconductor dies may include various types of integrated circuits, such as system-on-chip (SoC), application-specific integrated circuits (ASIC), system-in-package (SiP), high bandwidth memory (HBM), or dynamic random-access memory (DRAM) devices. The semiconductor dies may be connected to the interposer by one or more micro-bumps. A die module underfill layer may be formed on the interposer around the semiconductor dies. A upper molding material layer may be formed around the semiconductor dies and the die module underfill layer.

The semiconductor die module may be connected to the package substrate by one or more C4 bumps. A package underfill layer may be formed on the package substrate under the semiconductor die module and around the C4 bumps. The package substrate may include a package substrate solder mask and package substrate dielectrics and package substrate metal layers and a package substrate core layer.

The package structure may further include a ring structure on the package substrate around the semiconductor die module. The ring structure may include a lower ring including a lower ring first portion having a first width and a lower ring second portion having a second width greater than the first width, an upper ring attached to the lower ring second portion. The ring structure may have a novel design that may mitigate against a risk of delamination (e.g., adhesive delamination) in the package structure.

The novel ring structure of the package structure may be applicable to package structures including redistribution layers (RDL) with second passivation layers (e.g., super RDL with F-Pass2 structure). The package structure may integrate homogeneous or heterogeneous components. The homogeneous or heterogeneous components may be connected through an interposer in the semiconductor die module.

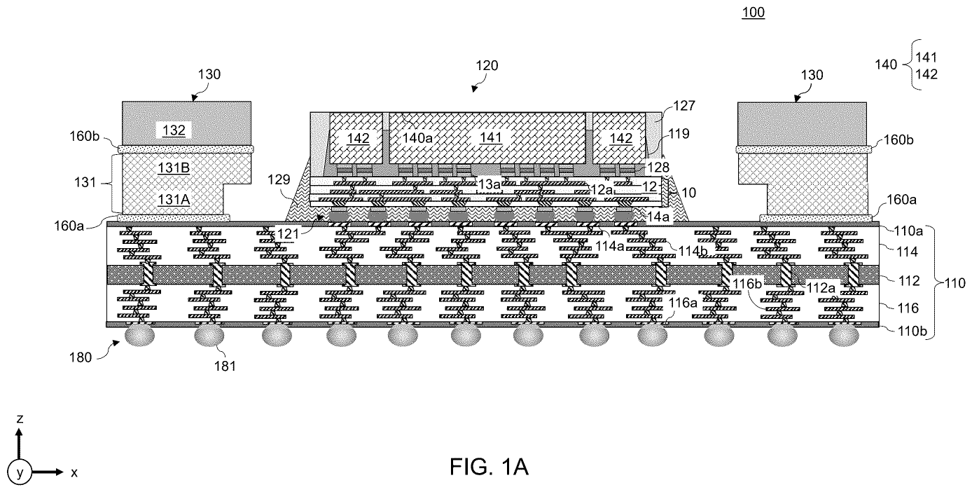

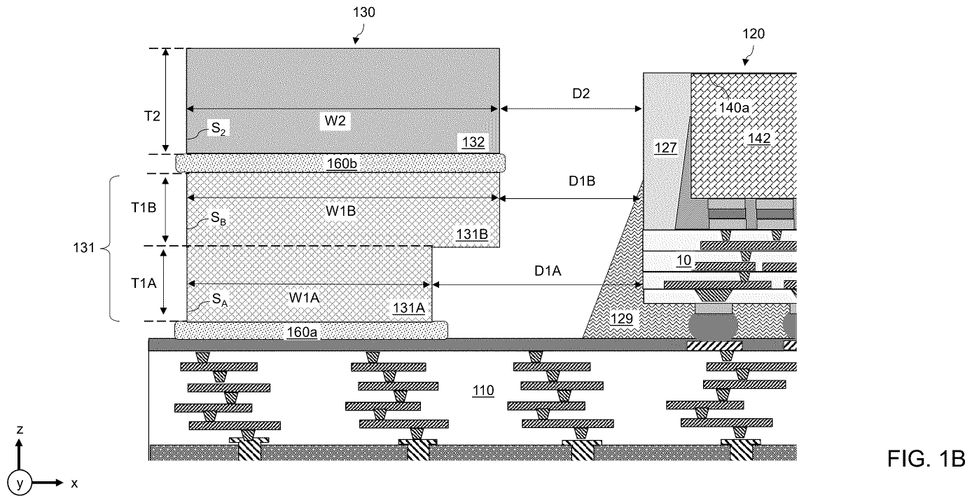

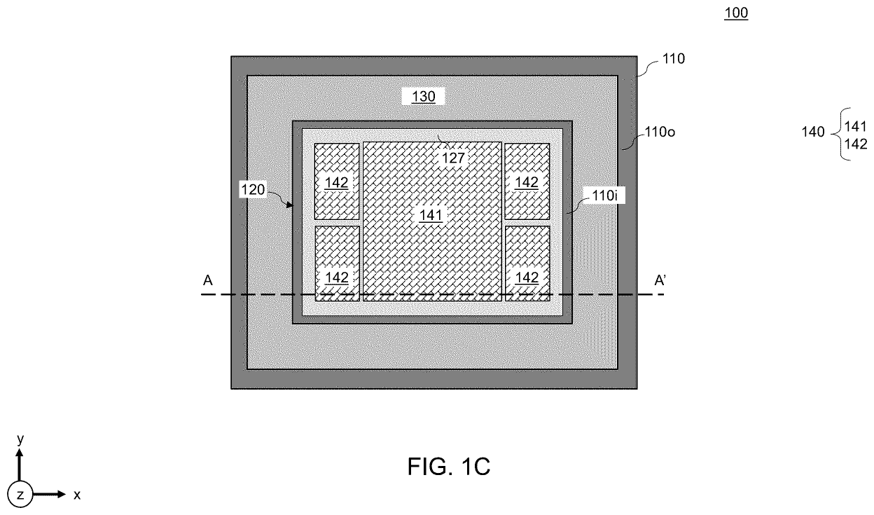

FIG. 1A is a vertical cross-sectional view of a package structure 100 (e.g., organic/silicon interposer package) according to one or more embodiments. FIG. 1B is a magnified vertical cross-sectional view of a ring structure 130 in the package structure 100 according to one or more embodiments. FIG. 1C is a top-down view (e.g., plan view) of the package structure 100 according to one or more embodiments. The vertical cross-sectional view in FIG. 1A is along the line A-A′ in FIG. 1C.

The package structure 100 may integrate homogeneous or heterogeneous components. Homogeneous components may refer to components of the same type or material, while heterogeneous components may include different types of devices or materials integrated within the same package. This flexibility in component integration may allow for diverse functionality and improved performance in various applications.

The package structure 100 may include a first set of semiconductor dies (e.g., primary dies such as a system on chip (SOC) die) and a second set of semiconductor dies (e.g., secondary dies such as memory/SOC dies, high bandwidth memory (HBM) dies, etc.). The first set of semiconductor dies may include, for example, first semiconductor die 141. The second set of semiconductor dies may include, for example, a second semiconductor die 142. The first semiconductor die 141 and second semiconductor die 142 may be referred to collectively as semiconductor dies 140.

Although the package structure 100 in FIGS. 1A-1C are illustrated as including a particular number of semiconductor dies 140 having a particular arrangement, the number of semiconductor dies 140 and the arrangement of the semiconductor dies 140 is not limited to any particular number and arrangement. In particular, the package structure 100 may include any number and arrangement of semiconductor dies 140 and any number and arrangement of semiconductor die sets.

Referring to FIGS. 1A and 1B, the package structure 100 may include a package substrate 110 and a semiconductor die module 120 attached to the package substrate 110. The semiconductor die module 120 may include the semiconductor dies 140. The package structure 100 may further include a ring structure 130 attached to the package substrate 110 around the semiconductor die module 120. The ring structure 130 may include a lower ring 131 attached to the package substrate 110 and an upper ring 132 attached to the lower ring 131. The lower ring 131 of the ring structure 130 may be attached to the package substrate 110 by a first adhesive layer 160a. The upper ring 132 of the ring structure 130 may be attached to the lower ring 131 by a second adhesive layer 160b. In at least one embodiment, the package structure 100 may include a chip-on-wafer-on-substrate design or an integrated fan-out design, etc. Other designs of the package structure 100 are within the contemplated scope of disclosure.

The package substrate 110 may serve as a foundation for the package structure 100, providing mechanical support and electrical connections for other components. In some embodiments, the package substrate 110 may include multiple layers of conductive and insulating materials to facilitate electrical routing and thermal management.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. In at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The metal interconnect structures 114b may constitute a redistribution layer (RDL) structure. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include a package substrate upper passivation layer 110a (e.g., solder mask) on the chip-side surface of the package substrate upper dielectric layer 114. The package substrate upper passivation layer 110a may partially cover the package substrate upper bonding pads 114a. The upper passivation layer 114a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The metal interconnect structures 114b may constitute a redistribution layer (RDL) structure. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include a package substrate lower passivation layer 110b (e.g., solder mask) on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) 180 including a plurality of solder balls 181 may be formed on the board-side surface of the package substrate lower dielectric layer 116. The solder balls 181 may allow the package structure 100 to be securely mounted on a substrate such as a printed circuit board (PCB) and electrically coupled to the PCB substrate. The solder balls 181 may contact the package substrate lower bonding pads 116a, respectively. The solder balls 181 may therefore be electrically connected to the package substrate upper bonding pads 114a by way of metal interconnect structures 116b, the through vias 112a and the metal interconnect structures 114b.

The solder balls 181 of the BGA may include a solder material including one or more of tin, copper, silver, bismuth, indium, zinc, and antimony. In particular, the solder material may include a tin-silver-copper alloy including about 3-4% silver, 0.5-0.7% copper, and the balance (95% or more) tin. A fourth metal such as zinc or manganese may be added to the tin-silver-copper alloy. The solder material may have a melting point in a range from 90 °C to 450 °C, and more particularly, in a range from about 220 °C to 260 °C.

The semiconductor die module 120 may be mounted on the package substrate 110 by forming C4 bumps 121 on the package substrate upper bonding pads 114a. The C4 bumps 121 may include a solder material similar to the solder material of the solder balls 181 in the BGA 180. In particular, the C4 bumps 121 may include one or more of tin, copper, silver, bismuth, indium, zinc, and antimony (e.g., a tin-silver-copper alloy including about 3-4% silver, 0.5-0.7% copper, and the balance (95% or more) tin).

A package underfill layer 129 may be formed under and around the semiconductor die module 120 and the C4 bumps 121 so as to fix the semiconductor die module 120 to the package substrate 110. The package underfill layer 129 may be formed of an epoxy-based polymeric material.

The semiconductor die module 120 may include an interposer 10 having a redistribution layer (RDL) structure. The interposer 10 may be electrically coupled to the package substrate 110 by the C4 bumps 121. The semiconductor dies 140 may be mounted on the interposer 10. The interposer 10 may facilitate complex interconnections between the semiconductor dies 140 and the package substrate 110, enabling advanced functionality in a compact form factor.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of polymer layers 12 and a plurality of redistribution layers 12a stacked alternately. The number of the polymer layers 12 and/or the number of redistribution layers 12a in the interposer 10 are not limited by the disclosure. While the interposer 10 is shown to have four (4) polymer layers 12, in other embodiments, a greater number or fewer number of layers may be used.

In at least one embodiment, the polymer layers 12 may include, for example, polyimide (PI), epoxy resin, acrylic resin, phenol resin, benzocyclobutene (BCB), poly-benzoxazole (PBO), or any other suitable polymer-based dielectric material. In some embodiments, the redistribution layers 12a may include conductive materials. The conductive materials may include metal such as copper, aluminum, nickel, titanium, a combination thereof or other suitable metals.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12 and may extend in the x-direction (e.g., first horizontal direction) and y-direction (e.g., second horizontal direction) on an upper surface of the polymer layers 12.

An upper passivation layer (not shown) may be formed on the chip-side surface of the interposer 10. The upper passivation layer may include silicon oxide, silicon nitride, low-k dielectric materials such as carbon-doped oxides, extremely low-k dielectric materials such as porous carbon doped silicon dioxide, a combination thereof or other suitable material.

One or more interposer upper bonding pads 13a may be located in the upper passivation layer on the chip-side surface of interposer 10. The upper passivation layer may at least partially cover the interposer upper bonding pads 13a. That is, the interposer upper bonding pads 13a may be at least partially exposed on the chip-side surface of the interposer 10. The interposer upper bonding pads 13a may be connected to the redistribution layers 12a. The interposer upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer (not shown) may be formed on the board-side surface of the interposer 10. The lower passivation layer may also include silicon oxide, silicon nitride, low-k dielectric materials such as carbon-doped oxides, extremely low-k dielectric materials such as porous carbon doped silicon dioxide, a combination thereof or other suitable material.

One or more interposer lower bonding pads 14a may be located on the board-side surface of interposer 10. The interposer lower bonding pads 14a may be bonded to and electrically connected to the redistribution layers 12a. The interposer lower bonding pads 14a may be located in the lower passivation layer. The lower passivation layer may at least partially cover the interposer lower bonding pads 14a. That is, the interposer lower bonding pads 14a may be at least partially exposed on the board-side surface of the interposer 10. The interposer lower bonding pads 14a may also include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

One or more integrated passive devices (IPDs) (not shown) may optionally be located on the board-side surface of interposer 10. The IPDs may be bonded to and electrically connected to the redistribution layers 12a. The IPDs may be located in the lower passivation layer. The IPDs may include an exposed portion that projects out from the lower passivation layer. The IPDs may include one or more electronic components such as resistors, capacitors, inductors, coils, chokes, microstriplines, impedance matching elements, baluns, etc. The IPDs may be electrically coupled to the semiconductor dies 140 through the interposer 10.

The semiconductor dies 140 may be mounted on the interposer 10 by micro-bumps 128 that may be bonded to the interposer upper bonding pads 13a. The semiconductor dies 140 may be electrically coupled to the metal interconnects 12a by the microbumps 128. The microbumps 128 may provide electrical pathways for signal trans-mission and power distribution between the semiconductor dies 140 and the interposer 10.

A die module underfill layer 119 may be formed around the microbumps 128 and between the semiconductor dies 140 and the interposer 10. The die module underfill layer 119 may be formed separately under each of the semiconductor dies 140. Alternatively, the die module underfill layer 119 may be formed continuously as one layer under all of the semiconductor dies 140 as illustrated in FIG. 1A. The die module underfill layer 119 may also be formed between each of the semiconductor dies 140. The die module underfill layer 119 may also be formed of an epoxy-based polymeric material.

Each of the semiconductor dies 140 may include, for example, a singular semiconductor die, a system on chip (SOC) die, or a system on integrated chips die, and may be implemented by chip-on-wafer-on-substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, a static random access memory (SRAM) die, etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure.

The semiconductor die module 120 may also include an upper molding material layer 127 formed around the semiconductor dies 140. The upper molding material layer 127 may provide additional protection and structural support for the components (e.g., semiconductor dies 140) within the semiconductor die module 120. The upper molding material layer 127 may also be formed on and around the die module underfill layer 119. The semiconductor dies 140 may have a substantially coplanar upper surface 140a. An upper surface of the upper molding material layer 127 may be substantially coplanar with the upper surface 140a of the semiconductor dies 140.

In at least one embodiment, a height of an upper surface of the die module underfill layer 119 may be less than a height of the upper surface 140a of the semiconductor dies 140. In that case, the upper molding material layer 127 may be formed on sidewalls (inner sidewall and outer sidewall) of each of the semiconductor dies 140. In particular, the upper molding material layer 127 may be formed between and bonded to the sidewalls of each of the semiconductor dies 140. The upper molding material layer 127 may have an outer sidewall that is substantially aligned with the outer sidewall of the interposer 10. The upper molding material layer 127 may be formed, for example, of an epoxy molding compound (EMC).

The package structure 100 may also include a ring structure 130 that may be fixed to the package substrate 110 adjacent to the semiconductor die module 120. The ring structure may provide rigidity to the package substrate 110. The ring structure 130 may also function, for example, as a heat sink and help to dissipate heat in the package structure 100 (e.g., dissipate heat out of the package substrate 110). The ring structure 130 may also play a role in mitigating package warpage and improving the overall reliability of the package structure 100. The ring structure 130 may help distribute stresses more evenly across the package structure 100, potentially reducing the risk of delamination or other structural issues.

The ring structure 130 may be formed, for example, of metal, ceramic or polymer material. In at least one embodiment, the ring structure 130 may be formed of a metal or metal alloy including various metals such as copper, iron, aluminum, nickel, chromium, etc. In at least one embodiment, the ring structure 130 may include copper (e.g., with a nickel coating), an iron-nickel alloy (e.g., Alloy 42), a stainless steel (e.g., SUS430), a welded metal, etc. Other suitable metal materials for use in the ring structure 130 are within the contemplated scope of disclosure.

As illustrated in FIG. 1B, the ring structure 130 may include the lower ring 131 attached to the package substrate 110 by a first adhesive layer 160a and the upper ring 132 attached to the lower ring 131 by a second adhesive layer 160b. The lower ring 131 may be located between the package substrate 110 and the upper ring 132. In at least one embodiment, an entirety of the lower ring 131 may be located between the package substrate 110 and the upper ring 132.

The lower ring 131 may have a stepped ring design. The stepped ring design may provide several benefits when it comes to overall thickness of the package structure 100 and form factor. The stepped ring design of the lower ring 131 may help to control warpage of the package substrate 110 (e.g., package warpage) and may, therefore, improve the reliability and performance of the package structure 100. The stepped ring design of the lower ring 131 may also offer specific thermal management benefits. By incorporating the stepped ring design of the lower ring 131, the thermal path can be optimized to enhance heat dissipation. This design may allow for better distribution of heat away from the semiconductor die module 120 (e.g., away from the package structure 100), potentially reducing hotspots and improving overall thermal performance of the package structure 100.

This stepped configuration of the lower ring 131 may create an increased surface area for attachment between the lower ring 131 and the upper ring 132. The stepped ring design of the lower ring 131 may enhance an ability of the package structure 100 to withstand mechanical stresses such as bending or drop impacts by providing additional support and stability. The embodiment design may help distribute stress more evenly across the package structure 100, reducing the likelihood of damage during handling. The stepped ring design of the lower ring 131 may also increase a rigidity of the package structure 100, making it less susceptible to deformation under pressure. Overall, the stepped ring design of the lower ring 131 may offer improved protection com-pared to related ring structure designs.

In at least one embodiment, the lower ring 131 may have a lower ring first portion 131A having a first width W1A and a lower ring second portion 131B on the lower ring first portion 131A. The lower ring first portion 131A may be formed of substantially the same material as the lower ring second portion 131B. In at least one embodiment, the lower ring first portion 131A may be integrally formed as a unit with the lower ring second portion 131B (e.g., formed from a single piece of metal).

In at least one embodiment, an outer sidewall S_{A} of the lower ring first portion 131A may be substantially aligned with an outer sidewall S_{B} of the lower ring second portion 131B. The lower ring second portion 131B may have a second width W1B that is greater than the first width W1A. In at least one embodiment, the second width W1B may be at least 25% greater than the first width W1A.

The upper ring 132 may have a width W2 which is equal to or greater than the second width W1B of the lower ring second portion 131B. In at least one embodiment, the width W2 is no more than 20% greater than the second width W1B. In at least one embodiment, an outer sidewall S₂ of the upper ring 132 may be substantially aligned with the outer sidewall S_{B} of the lower ring second portion 131B. The novel ring structure may allow a size of the contact area between the upper ring 132 and the lower ring 131 to be increased to avoid delamination of the adhesive layer 160b.

The lower ring first portion 131A may also have a first thickness T1A and the lower ring second portion 131B may have a second thickness T1B that is less than, greater than or equal to the first thickness T1A. A ratio T1B/T1A may be in a range from 0.3 to 3. In at least one embodiment, the lower ring 131 may have an overall thickness in a range from 0.1 mm to 10 mm (e.g., 0.1 mm≤T1A+T1B≤10 mm).

The lower ring first portion 131A may have a first cross-sectional area A1A, where A1A=W1A×T1A. The lower ring second portion 131B may have a second cross-sectional area A1B, where A1B=W1B×T1B. A ratio A1B/A1A may be in a range from 1.1 to 5. In some embodiments, the ratio A1B/A1A may be in a range from 1.5 to 4. In some embodiments, the ratio A1B/A1A may be in a range from 2 to 3.

The upper ring 132 may have a thickness T2 that is equal to or greater than the second thickness T1B of the lower ring second portion 131B. In at least one embodiment, the thickness T2 may be no more than 50% greater than the thickness T1B. The upper ring 132 may have a cross-sectional area A2, where A2=W2×T2. The cross-sectional area A2 of the upper ring 132 may be equal to or greater than the second cross-sectional area A1B of the lower ring second portion 131B. A ratio A1B/A2 may be in a range from 0.2 to 1. In some embodiments, the ratio A1B/A2 may be in a range from 0.3 to 0.9. In some embodiments, the ratio A1B/A2 may be in a range from 0.4 to 0.8. A height of an upper surface of the upper ring 132 (e.g., distance in the z-direction from the package substrate 110) may be greater than a height of the upper surface 140a of the semiconductor devices 140. In at least one embodiment, a height of an upper surface of the upper ring 132 may be at least 10% greater than the height of the upper surface 140a of the semiconductor devices 140.

The lower ring first portion 131A may be located away from the semiconductor die module 120 (e.g., from the interposer 10 of the semiconductor die module 120) by a distance D1A. In at least one embodiment, the distance D1A may be in a range from 1 mm to 5 mm. Other distances between the lower ring first portion 131A and the semiconductor die module 120 are within the contemplated scope of disclosure.

The lower ring second portion 131B may be located away from the semiconductor die module 120 (e.g., from the upper molding material layer 127 of the semiconductor die module 120) by a distance D1B less than the distance D1A. In at least one embodiment, the distance D1A may be at least 25% greater than the distance D1B. The upper ring 132 may be separated from the semiconductor die module 120 (e.g., from the upper molding material layer 127 of the semiconductor die module 120) by a distance D2. The distance D2 may be less than or equal to the distance D1B. In at least one embodiment, the distance D1B may is no more than 20% greater than the distance D2.

A material of the lower ring 131 may be the same or different than a material of the upper ring 132. In at least one embodiment, the lower ring 131 may have a first coefficient of thermal expansion (CTE) that is less than or equal to a second CTE of the upper ring 132. In at least one embodiment, the first CTE of the lower ring 131 may be in a range from 3 ppm/°C to 20 ppm/°C. In at least one embodiment, the second CTE of the upper ring 132 may be at least 10% greater than the first CTE of the lower ring 131.

In at least one embodiment, the upper ring 132 may include copper having a CTE of about 17.3 ppm/°C and the lower ring 131 may include an iron-nickel alloy (e.g., Alloy 42) having a CTE of about 4.3. In at least one embodiment the upper ring 132 may include copper having a CTE of about 17.3 ppm/°C and the lower ring 131 may include stainless steel (e.g., SUS430) having a CTE of about 11. In at least one embodiment the upper ring 132 may include stainless steel (e.g., SUS430) having a CTE of about 11 and the lower ring 131 may include an iron-nickel alloy (e.g., Alloy42) having a CTE of about 4.3.

A material of the first adhesive layer 160a may be substantially the same as a material of the second adhesive layer 160b, or different than the material of the second adhesive layer 160b. When working with the stepped ring design, choosing the right adhesive materials may be important for ensuring strong bonding and durability. Adhesives with higher elongation and better adhesion properties are often preferred because they may accommodate the stress and movement that might occur due to the unique geometry of the stepped ring.

In at least one embodiment, the first adhesive layer 160a and the second adhesive layer 160b may have a Young's modulus value in a range from 10 MPa to 10 GPa. Each of the first adhesive layer 160a and the second adhesive layer 160b may include, for example, an epoxy-based adhesive or a silicone-based adhesive. Other adhesives are within the contemplated scope of this disclosure. In at least one embodiment, the Young's modulus of the second adhesive layer 160b may be greater than the Young's modulus of the first adhesive layer 160a. In at least one embodiment, the first adhesive layer 160a may include a silicon-based adhesive and the second adhesive layer 160b may include an epoxy-based adhesive. In at least one embodiment, the second adhesive layer 160b may have a thermal conductivity that is greater than a thermal conductivity of the first adhesive layer 160a which may help to assist in heat dissipation by the lower ring second portion 131B and the upper ring 132.

A thickness of the first adhesive layer 160a may be substantially the same as the thickness of the second adhesive layer 160b. In particular, the thickness of the first adhesive layer 160a and the thickness of the second adhesive layer 160b may each be in a range from 50 μm to 150 μm (e.g., about 100 μm). In at least one embodiment, the thickness of the second adhesive layer 160b may be greater than the thickness of the first adhesive layer 160a. In at least one embodiment, the thickness of the second adhesive layer 160b may be at least 20% greater than the thickness of the first adhesive layer 160a. In at least one embodiment, the thickness of the first adhesive layer 160a may be in a range from 50 μm to 150 μm (e.g., about 100 μm) and the thickness of the second adhesive layer 160b may be in a range from 180 μm to 300 μm (e.g., about 250 μm).

A width (e.g., in the x-direction) of the first adhesive layer 160a may be less than a width of the second adhesive layer 160b. In at least one embodiment, the width of the first adhesive layer 160a may be substantially equal to or greater than the first width W1A of the lower ring first portion 131A. In at least one embodiment, the width of the second adhesive layer 160b may be substantially equal to or greater than the second width W1B of the lower ring second portion 131B.

As illustrated in FIG. 1C, the semiconductor die module 120 may be located in a central portion of the package substrate 110. The ring structure 130 may be formed on the package substrate 110 so as to laterally surround the semiconductor die module 120 in a first horizontal direction (e.g., the x-direction) and a second horizontal direction (e.g., y-direction). It should be noted that the ring structure 130 may not continuously surround the semiconductor die module 120 and may not surround an entirety of the semiconductor die module 120. That is, the ring structure 130 may surround only a portion of the semiconductor die module 120. In particular, the ring structure 130 may be formed only at one or more of the corners of the semiconductor die module 120.

In the top-down view of FIG. 1C, the ring structure 130 may be separated from an outer edge of the package substrate 110 by a package substrate outer portion 110°. This may allow, for example, for the first adhesive layer 160a to spread during assembly of the package structure 100 (e.g., during attaching of the ring structure 130 to the package substrate 110). A width of the package substrate outer portion 110o may be substantially uniform around the entire periphery of the ring structure 130 or may vary around the periphery of the ring structure 130.

The ring structure 130 may be separated from the semiconductor die module 120 (e.g., from the package underfill layer 129) by a package substrate inner portion 110i. A width of the package substrate inner portion 110i may be substantially uniform around the entire periphery of the semiconductor die module 120 or may vary around the periphery of the semiconductor die module 120.

In the top-down view, an outer shape of each of the semiconductor die module 120 and the package substrate 110 may include a rectangular shape or a square shape. Other shapes are within the contemplated scope of disclosure. The semiconductor die module 120 and package substrate 110 may have a symmetrical arrangement in which an outer shape of the semiconductor die module 120 may be substantially the same as an outer shape of the package substrate 110. The semiconductor die module 120 and package substrate 110 may alternatively have an asymmetrical arrangement in which the outer shape of the semiconductor die module 120 may be different than the outer shape of the package substrate 110.

In at least one embodiment, each of the semiconductor die module 120 and the package substrate 110 may include a rectangular shape. In that embodiment, a longitudinal direction of the semiconductor die module 120 may be substantially the same as a longitudinal direction of the package substrate 110. In at least one embodiment, the longitudinal direction of the semiconductor die module 120 may be perpendicular to the longitudinal direction of the package substrate 110.

The semiconductor dies 140 may be arranged in the semiconductor die module 120 so that the first semiconductor die 141 is centrally located in the semiconductor die module 120. The second semiconductor dies 142 may be located on opposing sides of the semiconductor die module 120 (e.g., in the longitudinal direction of the semiconductor die module 120). The second semiconductor dies 142 may be substantially aligned in a direction perpendicular to the longitudinal direction of the semiconductor die module 120 (e.g., the y-direction).

As further illustrated in FIG. 1C, a shape of the ring structure 130 in the top-down view may be substantially the same as a shape of the package substrate 110. In at least one embodiment, the shape of the ring structure 130 may be different than the shape of the package substrate 110. The ring structure 130 have a square shape or rectangle shape in the top-down view. Other suitable shapes of the ring structure 130 may be within the contemplated scope of disclosure. For example, the ring structure 130 may have a circular shape, oval shape, hexagonal shape, octagonal shape, polygonal shape, etc.

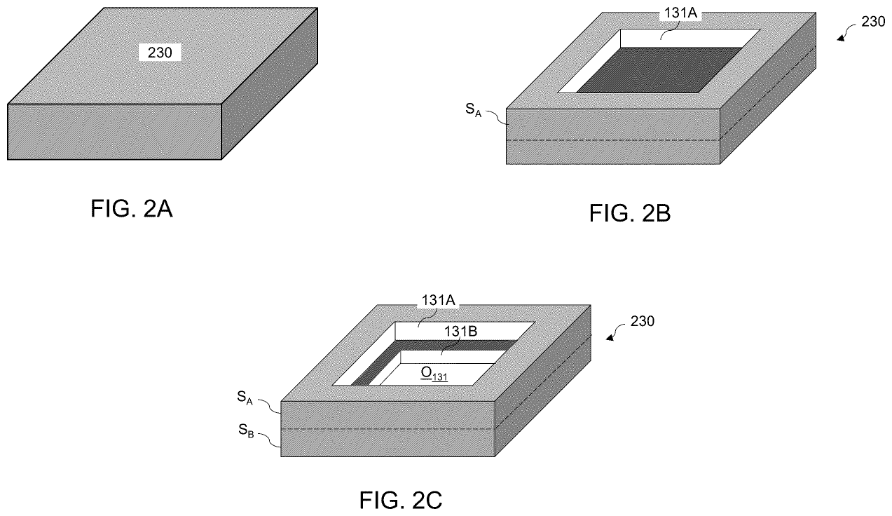

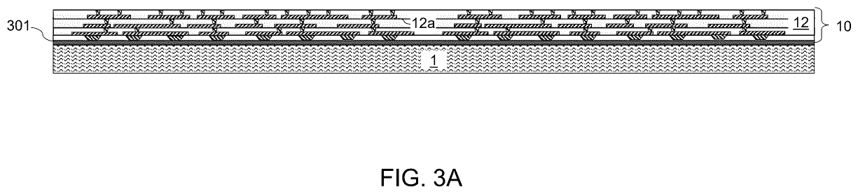

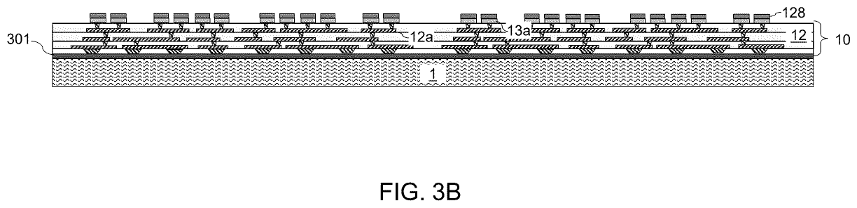

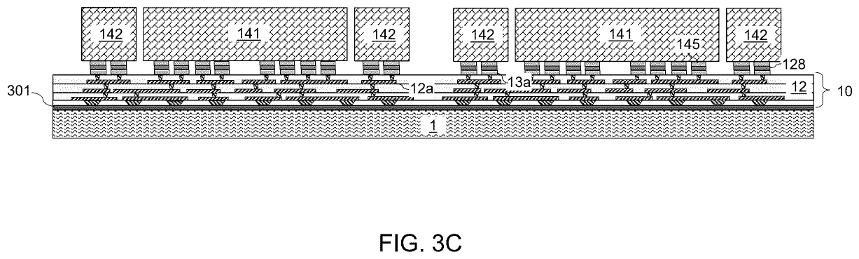

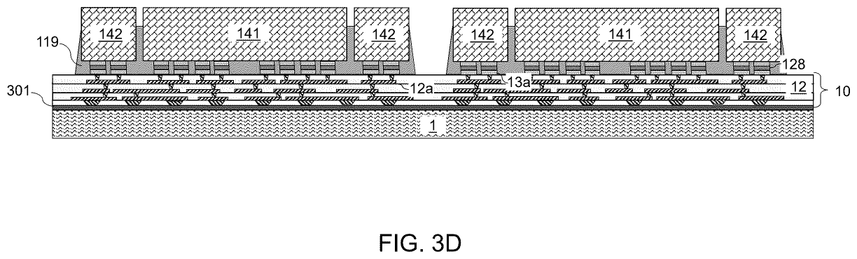

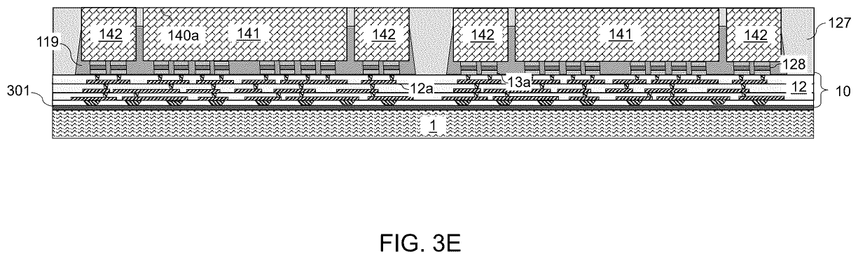

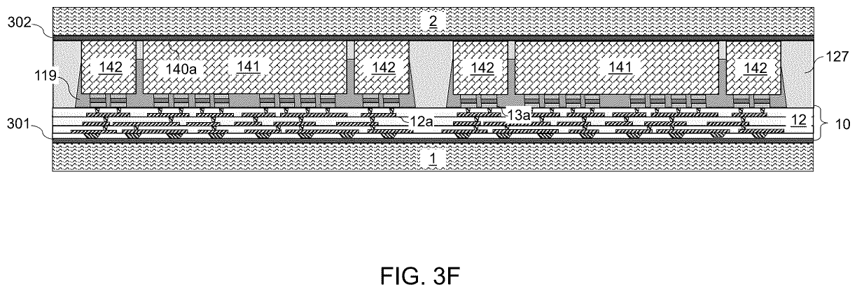

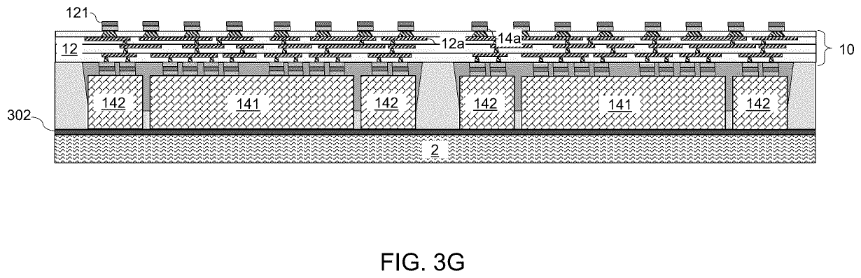

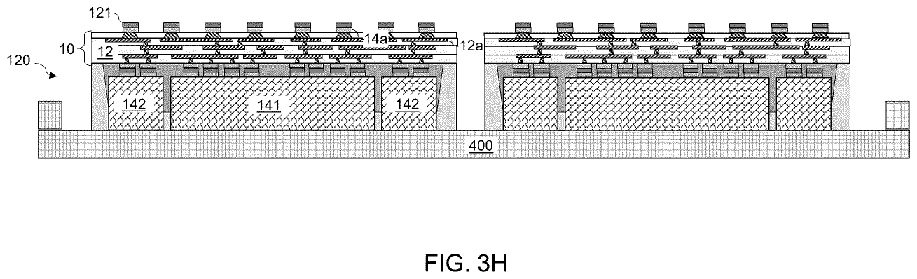

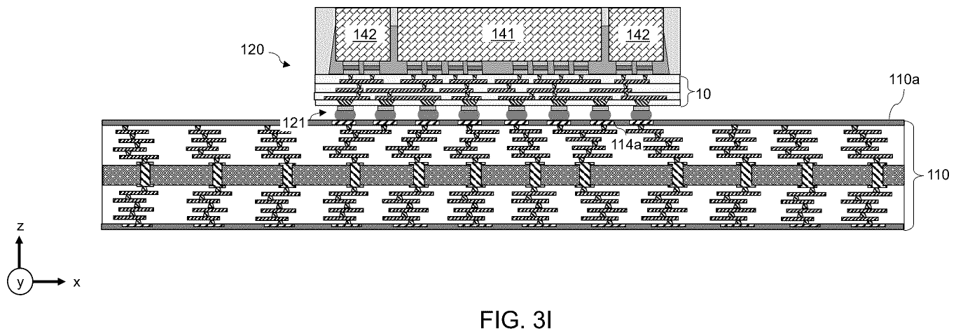

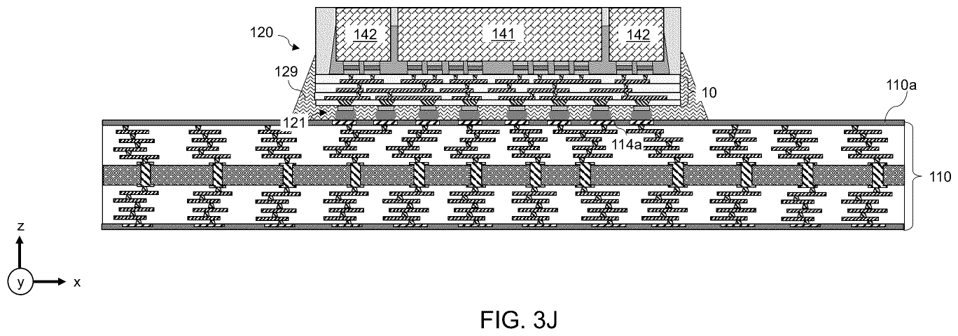

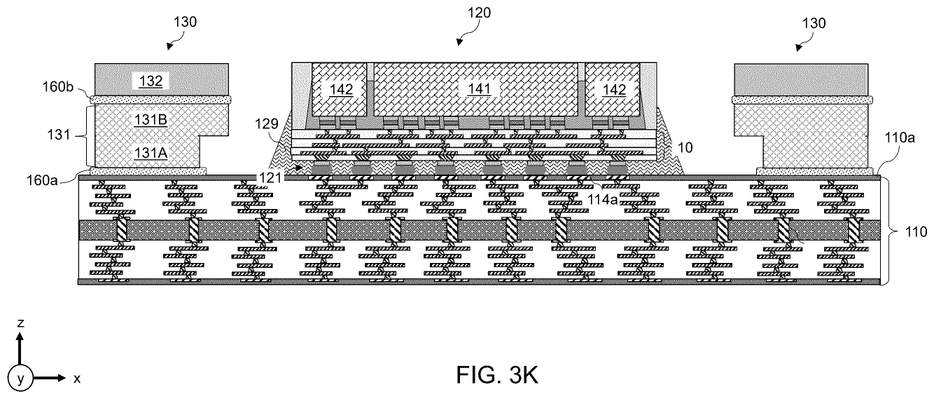

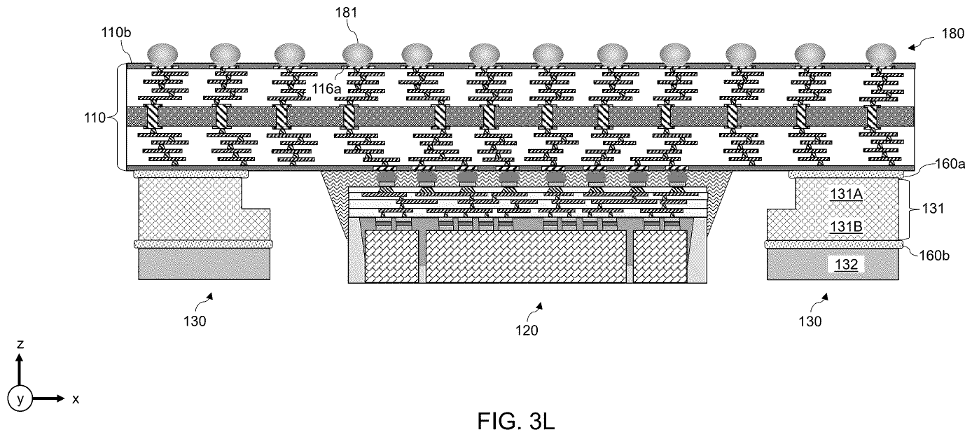

FIGS. 2A-3L illustrate various intermediate structures in a method making the package structure 100. In particular, FIGS. 2A-2C illustrate various intermediate structures in a method making the lower ring 131 of the package structure 100. FIGS. 3A-3L illustrate various intermediate structures in a method making the package structure 100.

It should be noted that throughout the manufacturing process, various considerations may need to be addressed to ensure the quality and reliability of the package structure 100. These considerations may include, for example, material selection, temperature control, cleanliness, precision alignment, proper curing times and conditions, and quality control. By carefully considering these factors and optimizing each step of the manufacturing process, the assembly of the package structure 100 with its ring structure 130 may be achieved with high reliability and performance.

FIG. 2A is a perspective view of an intermediate structure including a metal sheet 230, according to one or more embodiments. The metal sheet 230 may include, for example, a metal material such as copper, copper alloy, iron-nickel alloy, stainless steel, etc. Other metal materials are within the contemplated scope of this disclosure. An outer shape of the metal sheet 230 may include a rectangular shape or square shape. Other shapes are within the contemplated scope of disclosure. The outer shape of the metal sheet 230 may be substantially the same as the outer shape of the lower ring 131 (see FIG. 1C). The dimensions of the metal sheet 230 in the x-direction and in the y-direction may be substantially the same as the dimensions of the lower ring 131 (see FIG. 1C) in the x-direction and in the y-direction, respectively.

A thickness (in the z-direction) of the metal sheet 230 may be substantially uniform over the entire area of the metal sheet 230. The thickness of the metal sheet 230 may be substantially equal to a sum of the first thickness T1A of the inner ring first portion 131A and the second thickness T1B of the inner ring second portion 131B (see FIG. 1B). In at least one embodiment, the thickness of the metal sheet 230 may be in a range from 0.1 mm to 10 mm.

FIG. 2B is a perspective view of the metal sheet 230 including the lower ring first portion 131A, according to one or more embodiments. The metal sheet 230 in FIG. 2A may be subjected to processing to form the lower ring first portion 131A in the metal sheet 230. In particular, the processing may include stamp pressing the metal sheet 230 using a stamping press. The stamping press may include at least a 60-ton stamping press. The processing may alternatively include a milling process such as a computer numerical control (CNC) milling process using a CNC milling machine.

FIG. 2C is a top-down view of the metal sheet 230 including the lower ring second portion 131B, according to one or more embodiments. As illustrated in FIG. 2C, the lower ring second portion 131B may be formed in the metal sheet 230 by forming an opening O₁₃₁ in the center of the metal sheet 230. The metal sheet 230 in FIG. 2B may be subjected to processing (e.g., stamp pressing, CNC milling, etc.) to form the opening O₁₃₁ in the metal sheet 230. In particular, the processing used to form the opening O₁₃₁ may be the same processing or different processing than that used to form the lower ring first portion 131A in FIG. 2B.

FIG. 3A is a vertical cross-sectional view of an intermediate structure including the interposer 10 (e.g., organic interposer) formed on a first carrier substrate 1 (e.g., carrier wafer) according to an embodiment of the present invention. It should be noted that a plurality of semiconductor die modules 120 may be formed concurrently as illustrated in FIGS. 3A-3H.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used.

An adhesive layer 301 may be applied to the top surface of the first carrier substrate 1. In at least one embodiment, the first carrier substrate 1 may include an optically transparent material such as glass or sapphire. In this embodiment, the adhesive layer 301 may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer 301 may include a thermally decomposing adhesive material. For example, the adhesive layer 301 may include an acrylic pressure-sensitive adhesive that decomposes at an elevated temperature. The debonding temperature of the thermally decomposing adhesive material may be in a range from 150 °C to 400 °C. Other suitable thermally decomposing adhesive materials that decompose at other temperatures are within the contemplated scope of disclosure.

A plurality of dielectric layers 12 and plurality of redistribution layers 12a may be alternately formed on the first carrier substrate 1 (e.g., on the adhesive layer 301 on the first carrier substrate 1). It should be noted that although FIG. 3A illustrates four dielectric layers 12 and three redistribution layers 12a, more or fewer dielectric layers 12 and redistribution layers 12a are contemplated by the present disclosure.

Each dielectric layer 12 may each be formed, for example, by depositing (e.g., by CVD, PVD or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

FIG. 3B is a vertical cross-sectional view of an intermediate structure including the microbumps 128, according to an embodiment of the present invention. As illustrated in FIG. 3B, the interposer upper bonding pads 13a may be formed on the uppermost dielectric layer 12. The interposer upper bonding pads 13a may include any metallic material that may be bonded to a solder material. In at least one embodiment, the interposer upper bonding pads 13a may include an underbump metallurgy (UBM) layer stack deposited over the adhesive layer 301.

The interposer upper bonding pads 13a may be formed, for example, by an electroplating process. The interposer upper bonding pads 13a may alternatively be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process to form the interposer upper bonding pads 13a. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

The upper passivation layer (not shown) may optionally be formed on the chip-side surface of the interposer 10 and over the interposer upper bonding pads 13a. The upper passivation layer may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, chemical mechanical polishing (CMP), etc.) so as to form the upper passivation layer 13.

A solder layer may then be formed on the interposer upper bonding pads 13a to form the microbumps 128. The solder layer may be formed on the interposer upper bonding pads 13a, for example, by an electroplating process. Other methods of forming the solder layer are within the contemplated scope of disclosure.

FIG. 3C is a vertical cross-sectional view of an intermediate structure including the first semiconductor die 141 and second semiconductor die 142 (collectively referred to as semiconductor dies 140), according to one or more embodiments. The semiconductor dies 140 may be placed on the interposer 10, for example, by using an electro-mechanical pick-and-place (PNP) machine. Each of the semiconductor dies 140 may then be bonded to the interposer 10 by one or more microbumps 128 (e.g., top die joints). In at least one embodiment, the microbumps 128 may include a two-dimensional array of microbumps 128.

Each of the semiconductor dies 140 may include die bonding pads 145. The die bonding pads 145 may be formed of a substantially same material as the interposer upper bonding pads 13a. The semiconductor dies 140 may be attached to the interposer 10 by attaching the die bonding pads 145 to the interposer upper bonding pads 13a using a C2 bonding process, (e.g., solder bonding). In the C2 bonding process, an upper microbump portion (e.g., die bonding pad 145) may be positioned over a lower microbump portion (e.g., solder layer formed on the interposer upper bonding pads 13a) on the interposer 10. The intermediate structure may then be heated to cause reflow of the solder portion and form the solder joint of microbump 128.

Other methods of bonding the semiconductor dies 140 to the interposer 10 are within the contemplated scope of disclosure. In at least one embodiment, each of the semiconductor dies 140 may be bonded to the interposer 10 by a dual bond (e.g., direct bond) that may include a dielectric-to-dielectric bond (e.g., polymer-to-polymer bond) and a metal-to-metal bond. In that embodiment, the die bonding pads 145 of the semiconductor dies 140 may be positioned on the interposer upper bonding pads 13a. In addition, a dielectric layer (e.g., oxide layer, polymer layer, etc.) of the semiconductor dies 140 may be positioned on the upper passivation layer (not shown) of the interposer 10. The intermediate structure may then be heated to bond the die bonding pads 145 of the semiconductor dies 140 to the interposer upper bonding pads 13a and concurrently bond the dielectric layer of the semiconductor dies 140 to the upper passivation layer.

FIG. 3D is a vertical cross-sectional view of an intermediate structure including the die module underfill layer 119 (e.g., microbump underfill) according to one or more embodiments. The die module underfill layer 119 may be applied by depositing, dispensing and/or injecting an epoxy-based polymeric material onto the interposer 10. The epoxy-based polymeric material may be applied on the interposer 10 so as to be formed under the semiconductor dies 140 and around the microbumps 128. In at least one embodiment, the epoxy-based polymeric material may fill substantially all of the gaps between the semiconductor dies 140 and the interposer 10. The die module underfill layer 119 may then be cured, for example, in a box oven for duration in a range from 60 minutes to 120 minutes at a temperature in a range from 120 °C to 180 °C to provide the die module underfill layer 119 with a sufficient stiffness and mechanical strength.

FIG. 3E is a vertical cross-sectional view of an intermediate structure including the upper molding material layer 127, according to one or more embodiments. The upper molding material layer 127 (e.g., encapsulant layer) may be formed by a sequence of an over-molding process and a planarization process. In particular, the upper molding material layer 127 may include an epoxy polymer material (e.g., an epoxy molding compound (EMC). The upper molding material layer 127 may be formed on the interposer 10 and fill in the gaps between the semiconductor dies 140. The upper molding material layer 127 may encapsulate (e.g., in the x-direction and y-direction) the semiconductor dies 140. The upper molding material layer 127 may be formed, for example, by a deposition process such as CVD, PECVD, PVD, spin coating, lamination or other suitable deposition technique.

The upper molding material layer 127 may be deposited so as to completely cover the semiconductor dies 140 and the die module underfill layer 119. After the upper molding material layer 127 has cured, a planarization process may then be used to make an upper surface of the upper molding material layer 127 substantially coplanar with the upper surface 140a of the semiconductor dies 140. The planarization process may be performed on the upper surface of the upper molding material layer 127 until an upper surface of the semiconductor dies 140 are exposed. The planarization process may include, for example, a mechanical grinding process and/or a CMP process. Other means of planarizing the upper surface of the upper molding material layer 127 and upper surface 140a of the semiconductor dies 140 is within the contemplated scope of disclosure.

FIG. 3F illustrates a vertical cross-sectional view of an intermediate structure including a second carrier substrate 2, according to one or more embodiments. As illustrated in FIG. 3F, after the upper molding material layer 127 has been cured and planarized (e.g., by grinding, CMP, etc.), the second carrier substrate 2 may be attached to the intermediate structure of FIG. 3E. In particular, an adhesive layer 302 (e.g., substantially similar to the adhesive layer 301) may be formed on the upper surface of the upper molding material layer 127 and the upper surface 140a of the semiconductor dies 140. The second carrier substrate 2 may then be attached to the upper surface of the upper molding material layer 127 and the upper surface 140a of the semiconductor dies 140 by the adhesive layer 302. The intermediate structure of FIG. 3E may then be inverted and the first carrier substrate 1 may be detached from the lower polymer layer 12 of the interposer 10.

The first carrier substrate 1 may be detached from the interposer 10, for example, by deactivating the adhesive layer 301 adhering the first carrier substrate 1 to the interposer 10. The adhesive layer 301 may be deactivated, for example, by a thermal anneal at an elevated temperature (e.g., for a thermally-deactivated adhesive material, or by exposing the adhesive layer 301 to ultraviolet light (e.g., for an ultraviolet-deactivated adhesive material).

FIG. 3G illustrates a vertical cross-sectional view of an intermediate structure including the interposer lower bonding pads 14a, according to one or more embodiments. As illustrated in FIG. 3G, the interposer lower bonding pads 14a may then be formed on the lower polymer layer 12 of the interposer 10. The interposer lower bonding pads 14a may be formed using substantially the same materials and substantially the same processes as described above for the interposer upper bonding pads 13a. In particular, the interposer lower bonding pads 14a may be formed by an electroplating process or by a photolithographic process. The lower passivation layer (not shown) may then optionally be formed on the lower polymer layer 12 of the interposer 10 and over the interposer lower bonding pads 14a. The lower passivation layer may be formed using the same materials and processes described above for the upper passivation layer. The lower passivation layer may then be etched by a suitable etching process (e.g., by wet etching, dry etching, etc.) to form openings over the interposer lower bonding pads 14a and expose a surface of the interposer lower bonding pads 14a.

The C4 bumps 121 may then be formed by forming a solder layer on the interposer lower bonding pads 14a. The solder layer may be formed, for example, by an electroplating process or by a suitable deposition process. Other means of forming the solder layer are within the contemplated scope of disclosure. The C4 bumps 121 may include, for example, solder bumps formed in the openings in the lower passivation layer over the interposer lower bonding pads 14a. The plurality of C4 bumps 121 may contact the interposer lower bonding pads 14a through the openings in the lower passivation layer. In at least one embodiment, the C4 bumps 121 may be formed by forming one or more underbump metallization (UBM) layers (not shown) on the interposer lower bonding pads 14a, forming contact pads on the UBM layers, and forming the solder layer on the contact pads.

FIG. 3H illustrates a vertical cross-sectional view of the intermediate structure after a dicing process, according to one or more embodiments. As illustrated in FIG. 3H, after the C4 bumps 121 are formed, the second carrier substrate 2 may be debonded from the intermediate structure of FIG. 3G. The second carrier substrate 2 may be debonded from the intermediate structure by a process similar to the process described above for debonding the first carrier substrate 1. In particular, the second carrier substrate 2 may be detached by deactivating the adhesive layer 302 adhering the second carrier substrate 2 to the intermediate structure (e.g., wafer). The adhesive layer 302 may be deactivated, for example, by a thermal anneal at an elevated temperature (e.g., for a thermally-deactivated adhesive material, or by exposing the adhesive layer 302 to ultraviolet light (e.g., for an ultraviolet-deactivated adhesive material).

After the second carrier substrate 2 has been debonded from the intermediate structure, the wafer containing the intermediate structure may be attached to a dicing tape that may be formed over a frame 400 (e.g., metal or plastic frame). The dicing tape may hold the wafer securely in place. The frame mount 500 may provide physical support to the intermediate structure and ensure that the intermediate structure is securely held in place during the fabrication process. A dicing saw may then be used to cut the wafer so as to separate the individual semiconductor die modules 120.

FIG. 3I illustrates a vertical cross-sectional view of an intermediate structure in which the semiconductor die module 120 may be mounted on the package substrate 110, according to one or more embodiments. The semiconductor die module 120 may be mounted on the package substrate 110, for example, by a flip chip bonding (FCB) process. The semiconductor die module 121 may be positioned over the package substrate 110, for example, by an electromechanical pick-and-place (PNP) machine. The C4 bumps 121 on the semiconductor die module 121 may then be lowered onto the package substrate upper bonding pads 114a of the package substrate 110. The intermediate structure may then be heated in order to collapse the C4 bumps 121 and bond the C4 bumps 121 to the package substrate upper bonding pads 114a.

FIG. 3J illustrates a vertical cross-sectional view of an intermediate structure in which the package underfill layer 129 may be formed on the package substrate 110 according to one or more embodiments. The package underfill layer 129 may be formed of an epoxy-based polymeric material. As illustrated in FIG. 3J, the package underfill layer 129 may be formed (e.g., injected) under and around the semiconductor die module 120 and the C4 bumps 121 to the package substrate 110. The package underfill layer 129 may then be cured, for example, in a box oven for duration in a range from 60 minutes to 120 minutes at a temperature in a range from 120 °C to 180 °C to provide the package underfill layer 129 with a sufficient stiffness and mechanical strength.

FIG. 3K illustrates a vertical cross-sectional view of an intermediate structure including the ring structure 130 on the package substrate 110 according to one or more embodiments. After the package underfill layer 129 has been formed under and around the semiconductor die module 120, and after the lower ring 131 is formed (e.g., see FIGS. 2A-2C), the ring structure 130 may be attached to the package substrate 110.

The application of the first adhesive layer 160a to the package substrate 110 may be performed using techniques such as dispensing, screen printing, or lamination. The choice of application method may depend on factors such as the viscosity of the adhesive material and the desired thickness of the adhesive layer. In at least one embodiment, the first adhesive layer 160a may be applied using a dispensing tool. The dispensing tool may include, for example, an electromechanical dispensing tool. The electromechanical dispensing tool may be programmed to dispense a measured amount of adhesive material for the first adhesive layer 160a. The dispensing tool may dispense the adhesive material for each of the first adhesive layer 160a in a frame shape around the semiconductor die module 120. At the time of application, the first adhesive layer 160a may be sufficiently rigid to form a semi-solid bead on the surface of the package substrate 110. In at least one embodiment, a viscosity of the first adhesive layer 160a at the time of application may be 50,000 centipoise (cp) or greater. The shape of the semi-solid bead may remain substantially unchanged between the time of application by the dispensing tool and the later time of attaching the ring structure 130. The location of the frame shape of the first adhesive layer 160a may correspond to a location of the ring structure 130 (e.g., see FIG. 1C).

The lower ring 131 may then be moved into a position over the first adhesive layer 160a using an electromechanical pick-and-place (PNP) machine. The lower ring 131 may be substantially aligned with the first adhesive layer 160a. The lower ring 131 may then be lowered onto the first adhesive layer 160a so that the bottom surface of the lower ring 131 contacts an upper surface of the first adhesive layer 160a.

The lower ring 131 may then be pressed by a pressing force downwardly onto the first adhesive layer 160a. In at least one embodiment, the lower ring 131 may pressed by the electromechanical pick-and-place (PNP) machine onto the first adhesive layer 160a. The pressing force may be applied, for example, by a contact structure (not shown) that contacts an upper surface of the lower ring 131 around an entire periphery of the semiconductor die module 120 (e.g., see FIG. 1C). In at least one embodiment, the contact structure may have a size (e.g., area) greater than a size (e.g., area) of the lower ring 131. In at least one embodiment, a length (in the x-direction) and width (in the y-direction) of the contact structure may be greater than the length and width of the lower ring 131. A pressing of the lower ring 131 onto the first adhesive layer 160a may deform the first adhesive layer 160a so as to completely fill any gap between the lower ring 131 and the package substrate 110. The pressing force applied by the contact structure to the lower ring 131 may be substantially uniform around the entire periphery of the semiconductor die module 120. In at least one embodiment, the intermediate structure may be heated as the lower ring 131 is pressed onto the first adhesive layer 160a. In at least one embodiment, the intermediate structure may be heated to a temperature in a range from 120 °C to 180 °C (e.g., at about 150 °C) as the lower ring 131 is pressed onto the first adhesive layer 160a.

The second adhesive layer 160b may be formed on the lower ring 131. The application of the second adhesive layer 160b on the lower ring 131 may be substantially similar to the application of the first adhesive layer 160a on the package substrate 110. In particular, the second adhesive layer 160b may be applied using techniques such as dispensing, screen printing, or lamination. The upper ring 132 may then be pressed onto the second adhesive layer 160b. A pressing of the upper ring 132 onto the second adhesive layer 160b may deform the second adhesive layer 160b so as to completely fill any gap between the upper ring 132 and the lower ring 131. It should be noted that the upper ring 132 may alternatively be attached to the lower ring 131 prior to attaching the lower ring 131 to the package substrate 110.

The ring structure 130 may then be clamped to the package substrate 110 for a period to allow the first adhesive layer 160a and the second adhesive layer 160b to cure and form a secure bond between the package substrate 110 and the ring structure 130. The clamping of the ring structure 130 to the package substrate 110 may be performed, for example, by using a heat clamp module. The heat clamp module may apply a uniform force across the upper surface of the ring structure 130 in the x-direction and the y-direction. The heat clamp module may be applied as the adhesive 160 is cured at a temperature in a range from 120 °C to 180 °C (e.g., at about 150 °C).

Alternatively, the ring structure 130 may be placed on a surface (e.g., a flat surface), and the semiconductor die module 120 (which is mounted on the package substrate 110) may be inverted and inserted down into the ring structure 130. A downward force may then be applied to the package substrate lower passivation layer 110b of the package substrate 110. The ring structure 130 may then be clamped to the package substrate 110 and the adhesive cured so as to bond the package substrate 110 to the ring structure 130.

FIG. 3L illustrates a vertical cross-sectional view of an intermediate structure in which a plurality of solder balls 181 may be formed on the package substrate 110 according to one or more embodiments. The plurality of solder balls 181 may be formed on the lower bonding pads 116a through openings (not shown) in the package substrate lower passivation layer 110b. The solder balls 181 may be formed, for example, by an electroplating process. The solder balls 181 may be formed, for example, so as to be located under the ring structure 130 and under the semiconductor die module 120. The plurality of solder balls 181 may constitute the ball-grid array (BGA) 180 that may allow the package structure 100 to be securely mounted (e.g., by surface mount technology (SMT)) on a substrate such as a printed circuit board and electrically coupled to the substrate. Formation of the solder balls 181 may complete the formation of the package structure 100.

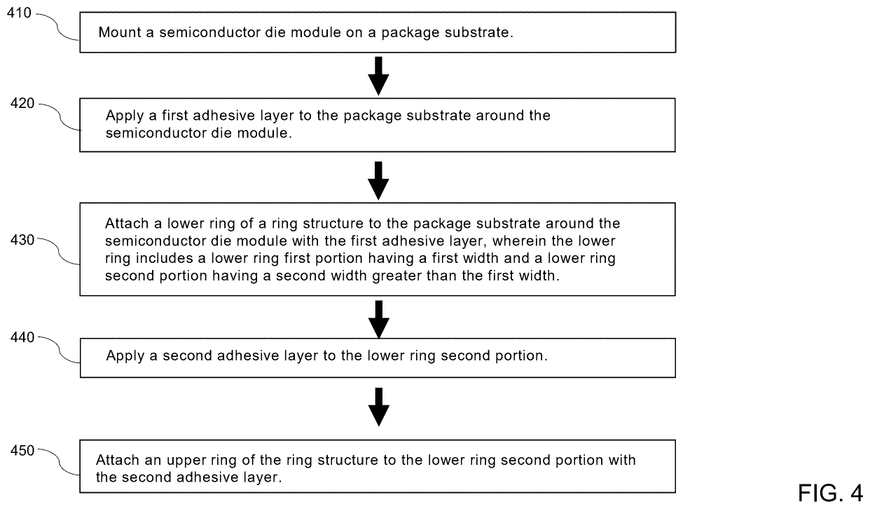

FIG. 4 is a flow chart illustrating a method of making the package structure 100 according to one or more embodiments. Step 410 includes mounting a semiconductor die module on package substrate. Step 420 includes applying a first adhesive layer to the package substrate around the semiconductor die module. Step 430 includes attaching a lower ring of a ring structure to the package substrate around the semiconductor die module with the first adhesive layer, wherein the lower ring includes a lower ring first portion having a first width and a lower ring second portion having a second width greater than the first width. Step 440 includes applying a second adhesive layer to the lower ring second portion. Step 450 includes attaching an upper ring of the ring structure to the lower ring second portion with the second adhesive layer.

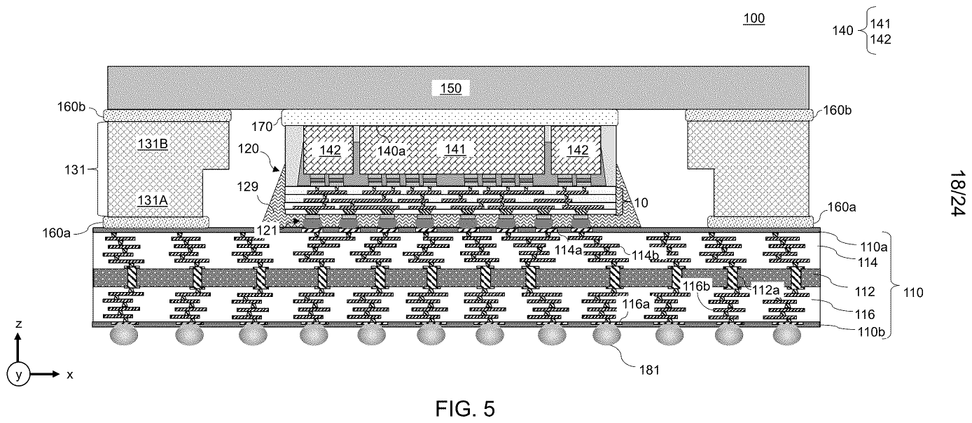

FIG. 5 is a vertical cross-sectional view of the package structure 100 having a first alternative configuration according to one or more embodiments. As illustrated in FIG. 5, in the first alternative configuration, the package structure 100 may include a TIM layer 170 on the semiconductor die module 120 and a package lid 150 on the TIM layer 170.

The TIM layer 170 may be formed on the semiconductor die module 120 to dissipate heat generated during operation of the package structure 100 (e.g., operation of semiconductor dies 140 including the first semiconductor die 141 and the second semiconductor die 142). The TIM layer 170 may include, for example, a metal TIM layer that may be attached to the semiconductor die module 120, for example, by a thermally conductive adhesive. In particular, the TIM layer 170 may contact the upper surface 140a of the semiconductor dies 140 and the upper surface of the upper molding material layer 127. The TIM layer 170 may have a low bulk thermal impedance and high thermal conductivity. The bond-line-thickness (BLT) (e.g., a distance between the package lid 150 and the semiconductor die module 120) may be less than about 100 μm, although greater or lesser distances may be used.

The package lid 150 may serve as a protective cover for the semiconductor die module 120. The package lid 150 may help to provide rigidity to the package structure 100 and may also help to dissipate heat from the package structure 100. The package lid 150 may be attached to the lower ring 131 by the second adhesive layer 160b. The package lid 150 may be separated from the upper surface of the lower ring 131 by the second adhesive layer 160a. In at least one embodiment, a height of an upper surface of the lower ring second portion 131B may be substantially uniform around an entirety of the lower ring second portion 131B. In at least one embodiment, a height of an upper surface of the lower ring second portion 131B may be greater than a height of the upper surface of the semiconductor die module 120 (e.g., a height of the upper surface 140a of the semiconductor dies 140). In at least one embodiment, the height of an upper surface of the lower ring second portion 131B may be no more than 100 μm greater than the height of the upper surface of the semiconductor die module 120. A thickness of the TIM layer 150 may be greater than a thickness of the second adhesive layer 160b. A thickness of the second adhesive layer 160b may be substantially uniform around an entirety of the lower ring 131. The package lid 150 should be in a plane substantially parallel to a plane of the package substrate 110.

The package lid 150 may contact at least a portion of the TIM layer 170 and may provide a cover for the semiconductor die module 120. In one or more embodiments, the package lid 150 may directly contact an entire upper surface of the TIM layer 170. The contact between the package lid 150 and the TIM layer 170 may enhance thermal conductivity and improve heat dissipation from the semiconductor die module 120.

The package lid 150 may have a thickness in the z-direction substantially the same as the thickness T2 of the upper ring 132 (see FIG. 1B). The package lid 150 may be formed of a substantially same material as the upper ring 132 (see FIG. 1A). The package lid 150 may be formed, for example, of metal, ceramic or polymer material. In one or more embodiments, Cu/CuS304/SUS430 may be used as a material for the package lid 150. The package lid 150 may have a substantially flat, planar shape. The package lid 150 may be mold-formed, punched or stamped or a CNC milling tool may be used to fabricate the package lid 150.

The package lid 150 may include a central region that is formed over a central portion of the semiconductor die module 120. An outer sidewall of the package lid 150 may be substantially aligned with the outer sidewall of the lower ring second portion SB (see FIG. 1B). This alignment may provide a uniform external profile for the package structure 100, which may be beneficial for manufacturing and integration processes.

In at least one embodiment, the package lid 150 may have a square shape or rectangle shape. Other suitable shapes of the package lid 150 may be within the contemplated scope of disclosure. The lower ring second portion 131B may be attached to a bottom surface of the package lid 150 (through the second adhesive layer 160b) continuously around the entire perimeter of the package lid 150. The bottom surface of the package lid 150 have an outer shape that corresponds to (e.g., is substantially the same as) the outer shape of the lower ring second portion 131B.

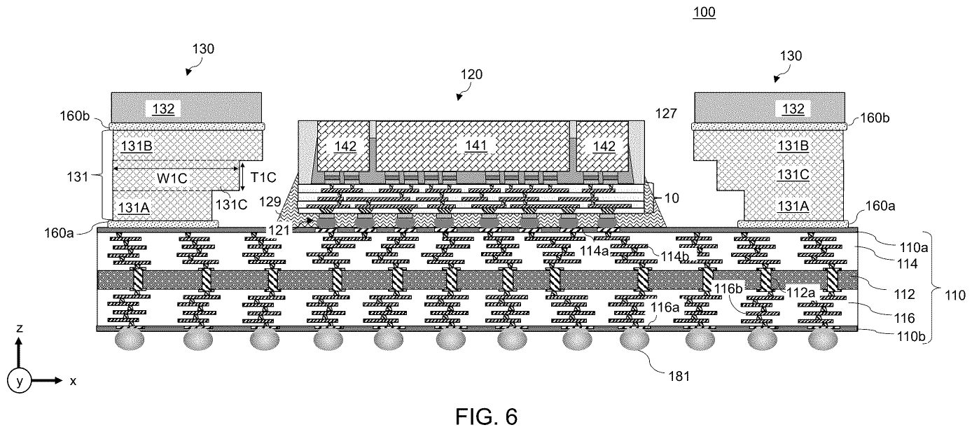

FIG. 6 is a vertical cross-sectional view of the package structure 100 having a second alternative configuration according to one or more embodiments. As illustrated in FIG. 6, the package structure 100 having the second alternative configuration may be substantially similar to the package structure 100 in FIGS. 1A-1C. However, unlike the package structure 100 in FIGS. 1A-1C, the lower ring 131 in the package structure 100 have the second alternative configuration may include more than two layers (e.g., more than two portions in the stepped design). In particular, the package structure 100 having the second alternative configuration may include a lower ring third portion 131C. The lower ring third portion 131C may be located between lower ring first portion 131A and the lower ring second portion 131B. The lower ring third portion 131C may have an outer sidewall that is substantially aligned with the outer sidewall SA of the lower ring first portion 131A and with the outer sidewall SB of the lower ring second portion 131B (see FIG. 1B). The lower ring third portion 131C may have a third width W1C greater than the first width W1A of the lower ring first portion 131A and less than a second width W1B of the lower ring second portion 131B (see FIG. 1B). In at least one embodiment, the third width W1C may be about one-half of the difference between the first width W1A of the lower ring first portion 131A and the second width W1B of the lower ring second portion 131B.

The lower ring third portion 131C may have a third thickness T1C that is substantially similar to the first thickness T1A of the lower ring first portion 131A and substantially similar to the second thickness T1B of the lower ring second portion 131B. In particular, the third thickness T1C may be less than, greater than or equal to the first thickness T1A and less than, greater than or equal to the second thickness T1B. In at least one embodiment, the lower ring 131 in the second alternative configuration of FIG. 6 may have an overall thickness in a range from 0.1 mm to 10 mm (e.g., 0.1 mm≤T1A+T1B+T1C≤10 mm).

The lower ring third portion 131C may also have a third cross-sectional area A1C, where A1C=W1C×T1C. The third cross-sectional area A1C may be greater than the first cross-sectional area A1A of the lower ring first portion 131A and less than the second cross-sectional area A1B of the lower ring second portion 131B.

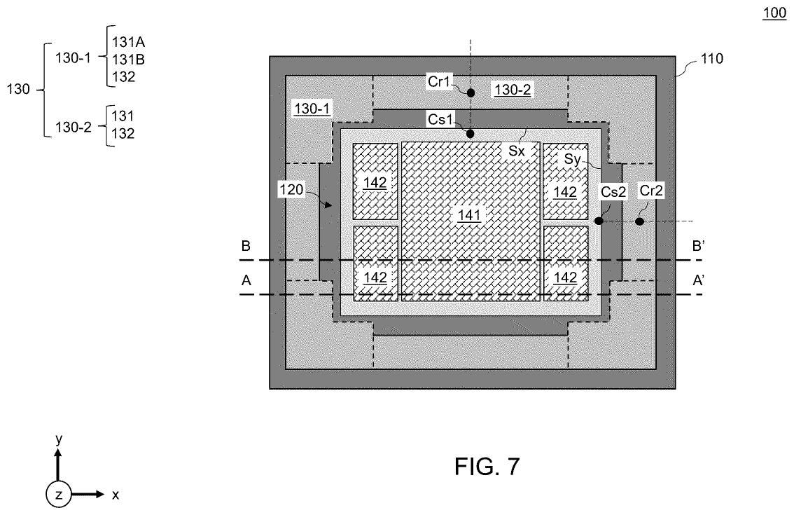

FIG. 7 is a top-down view of the package structure 100 having a third alternative configuration according to one or more embodiments. As illustrated in FIG. 7, the package structure 100 having the third alternative configuration may be substantially similar to the package structure 100 in FIGS. 1A-1C. However, unlike the package structure 100 in FIGS. 1A-1C, the package structure 100 having the third alternative configuration may have a ring structure 130 including a ring structure corner portion 130-1 located at a corner of the semiconductor die module 130, and a ring structure straight portion 130-2 along a side of the semiconductor die module 120. In particular, the ring structure 130 may include four ring structure corner portions 130-1 located at the four corners of the semiconductor die module 130, respectively. The ring structure 130 may also include four ring structure straight portion 130-2 located along the four sides of the semiconductor die module 120.

This alternative configuration of the ring structure 130 may allow the ring structure 130 to provide comprehensive support and protection around the entire perimeter of the semiconductor die module 120. In particular, this configuration of the ring structure 130 (e.g., having distinct corner and straight portions) may contribute to the overall structural integrity and reliability of the package structure 100. The arrangement may help distribute stresses more evenly around the semiconductor die module 120, potentially reducing the risk of delamination or other structural issues in the package structure 100.

As illustrated in FIG. 7, a center Cr1 of the ring structure straight portion 130-2 in the x-direction may be substantially aligned with a center Cs1 of the side Sx of the semiconductor die module 120 in the x-direction. In addition, a center Cr2 of the ring structure straight portion 130-2 in the y-direction may be substantially aligned with a center Cs2 of the side Sy of the semiconductor die module 120 in the y-direction. Further, a length of the ring structure straight portion 130-2 in the x-direction may be in a range from 60% to 80% of a length of the side Sx of the semiconductor die module 120 in the x-direction. A length of the ring structure straight portion 130-2 in the y-direction may be in a range from 60% to 80% of a length of the side Sy of the semiconductor die module 120 in the y-direction.

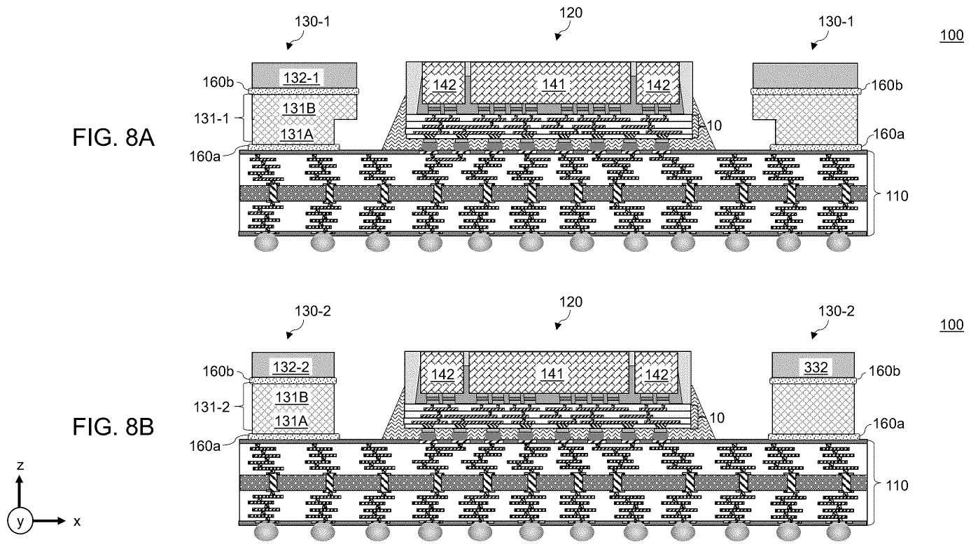

FIG. 8A is a vertical cross-sectional view of the package structure 100 having the third alternative configuration along the line A-A′ in FIG. 7, according to one or more embodiments. FIG. 8B is a vertical cross-sectional view of the package structure 100 having the third alternative configuration along the line B-B′ in FIG. 7, according to one or more embodiments. In particular, FIG. 8A provides a vertical cross-sectional view of the ring structure corner portion 130-1 and FIG. 8B provides a vertical cross-sectional view of the ring structure straight portion 130-2. It should be noted that the vertical cross-sectional view of the package structure 100 having the third alternative configuration in FIG. 8A is substantially similar to the vertical cross-sectional view of the package structure 100 in FIG. 1A.

As illustrated in FIG. 8A, the lower ring 131 in the package structure 100 having the third alternative configuration may include a lower ring corner portion 131-1 in the ring structure corner portion 130-1. The lower ring corner portion 131-1 may include the lower ring first portion 131A having the first width W1A and the lower ring second portion 131B having the second width W1B greater than the first width W1A (see FIG. 1B). As further illustrated in FIG. 8B, the lower ring 131 in the package structure 100 having the third alternative configuration may include a lower ring straight portion 131-2 in the ring structure straight portion 130-2. The lower ring straight portion 131-2 may include the lower ring first portion 131A having the first width W1A and the lower ring second portion 131B having a width substantially equal to the first width W1A.

As further illustrated in FIG. 8A, the upper ring 132 in the package structure 100 having the third alternative configuration may include an upper ring corner portion 132-1 in the ring structure corner portion 130-1. The upper ring corner portion 132-1 may have a width W2 equal to or greater than the second width W1B of the lower ring second portion 131B in the ring structure corner portion 130-1. As further illustrated in FIG. 8B, the upper ring 132 in the package structure 100 having the third alternative configuration may also include an upper ring straight portion 132-2 in the ring structure straight portion 130-2. The upper ring straight portion 132-2 may have a width substantially equal to the first width W1A of the lower ring first portion 131A and substantially equal to the second width W1B of the lower ring second portion 131B.

In at least one embodiment, the lower ring corner portion 131-1 may be integrally formed with the lower ring straight portion 131-2. In at least one embodiment, the upper ring corner portion 132-1 may be integrally formed with the upper ring straight portion 132-2.

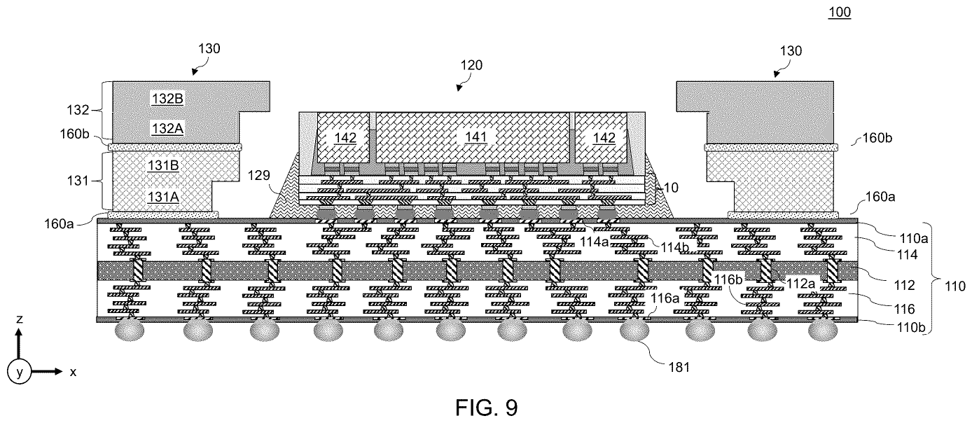

FIG. 9 is a vertical cross-sectional view of the package structure 100 having a fourth alternative configuration according to one or more embodiments. As illustrated in FIG. 9, the package structure 100 having the fourth alternative configuration may be substantially similar to the package structure 100 in FIGS. 1A-1C. However, unlike the package structure 100 in FIGS. 1A-1C, the package structure 100 having the fourth alternative configuration may include a ring structure 130 having an upper ring 132 having a stepped design. In particular, the stepped design of the upper ring 132 may be substantially similar to the stepped design of the lower ring 131.

In at least one embodiment, the upper ring 132 may include an upper ring first portion 132A and an upper ring second portion 132B. The upper ring first portion 132A may have a width equal to or greater than the second width W1B of the lower ring second portion 131B. The upper ring second portion 132B may have a width greater than the width of the upper ring first portion 132A. In at least one embodiment, the width of the upper ring second portion 132B may be at least 25% greater than the width of the upper ring first portion 132A.

The upper ring second portion 132B may have a thickness that is less than, greater than or equal to a thickness of the upper ring first portion 132A. A ratio of the thickness of the upper ring second portion 132B to the thickness of the upper ring first portion 132A may be in a range from 0.3 to 3. In at least one embodiment, the upper ring 132 may have an overall thickness that is substantially the same as the overall thickness of the lower ring 131. In at least one embodiment, the overall thickness of the upper ring 132 may be in a range from 0.1 mm to 10 mm.

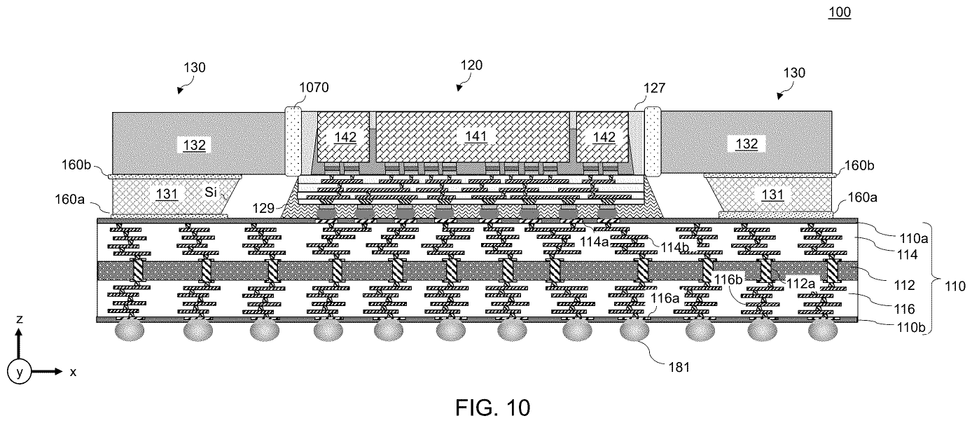

FIG. 10 is a vertical cross-sectional view of the package structure 100 having a fifth alternative configuration according to one or more embodiments. As illustrated in FIG. 10, the package structure 100 having the fifth alternative configuration may be substantially similar to the package structure 100 in FIGS. 1A-1C. However, unlike the package structure 100 in FIGS. 1A-1C, the package structure 100 having the fifth alternative configuration may include a ring structure 130 with a lower ring 131 having a tapered inner sidewall Si. In particular, the tapered inner sidewall Si of the lower ring 131 may replace the stepped design of the package structure 100 in FIGS. 1A-1C. In particular, the lower ring 131 may include a width that increases in a direction away from the package substrate 110.

The fifth alternative configuration may also include a TIM layer 1070 on a sidewall of the semiconductor die module 120 (e.g., on a sidewall of the upper molding material layer 127 and/or on a sidewall of the interposer 10). The upper ring 132 of the ring structure 130 may extend inwardly from the lower ring 131 and contact the TIM layer 1070 on the sidewall of the semiconductor die module 120. This configuration may allow the ring structure 130 to provide greater heat dissipation properties than a ring structure 130 that is not in contact with the semiconductor die module 120.

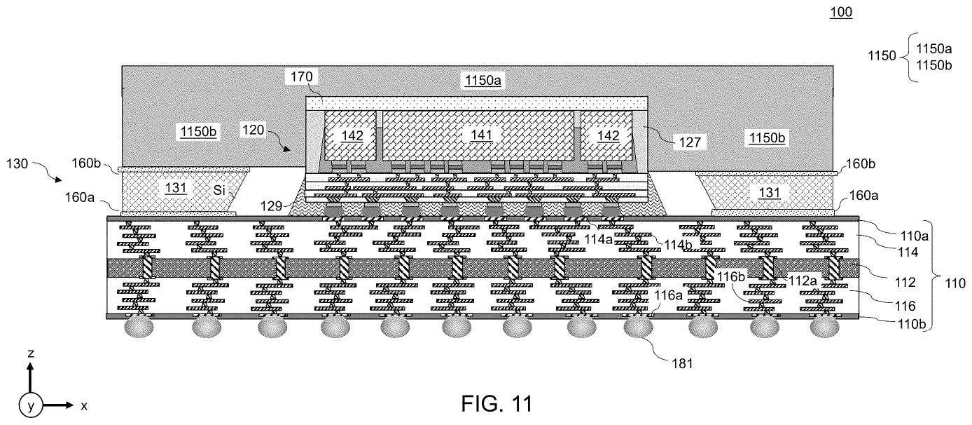

FIG. 11 is a vertical cross-sectional view of the package structure 100 having a sixth alternative configuration according to one or more embodiments. As illustrated in FIG. 11, the package structure 100 having the sixth alternative configuration may be substantially similar to the package structure 100 having the fifth alternative configuration in FIG. 10. In particular, the package structure 100 having the sixth alternative configuration may include a ring structure 130 with a lower ring 131 having a tapered inner sidewall Si.

However, unlike the package structure 100 having the fifth alternative configuration in FIG. 10, the package structure 100 having the sixth alternative configuration may include a package lid 1150 over the semiconductor die module 120 and attached to the lower ring 131. The package lid 1150 may be substantially similar to the package lid 150 in FIG. 5.

In particular, the package structure 100 having the sixth alternative configuration may include the TIM layer 170 on the upper surface of the semiconductor die module 120. The package lid 1150 may include a package lid plate portion 1150a contacting the TIM layer 170 over the upper surface of the semiconductor die module 120. The package lid 1150 may also include a package lid foot portion 1150b contacting a sidewall of the semiconductor die module 120 (e.g., contacting a sidewall of the upper molding material layer 127). The TIM layer 170 may optionally be formed on at least a portion of the sidewall of the semiconductor die module 120 so that the package lid foot portion 1150b may contact the sidewall of the semiconductor die module 120 through the TIM layer 170. In still other embodiments, the package lid foot portion 1150b may be spaced away from the sidewall of the semiconductor die module 120 (e.g., a sidewall of the upper molding material layer 127). The package lid foot portion 1150b may also be attached to the lower ring 131 of the ring structure 130. In particular, the package lid foot portion 1150b may be attached to the lower ring 131 by the second adhesive layer 160b. With this configuration, the package lid 1150 may be especially effective at dissipating heat generated by the semiconductor dies 140 in the semiconductor die module 120.

Referring to FIGS. 1A-11, a package structure 100 may include a package substrate 110, a semiconductor die module 120 on the package substrate 110, and a ring structure 130 on the package substrate 110 around the semiconductor die module 120, including a lower ring 131 including a lower ring first portion 131A having a first width W1A and a lower ring second portion 131B having a second width W1B greater than the first width W1A, and an upper ring 132 attached to the lower ring second portion 131B.

In one embodiment, the package structure 100 may further include a first adhesive layer 160a between the lower ring first portion 131A and the package substrate 110, and a second adhesive layer 160b between the lower ring second portion 131B and the upper ring 132. In one embodiment, the upper ring 132 may have a width W2 substantially the same as the second width W1B of the lower ring second portion 131B. In one embodiment, the lower ring first portion 131A may have a first cross-sectional area A1A and the lower ring second portion 131B may have a second cross-sectional area A1B greater than the first cross-sectional area A1A. In one embodiment, the upper ring 132 may have a cross-sectional area A2 equal to or greater than the second cross-sectional area A1B of the lower ring second portion 131B. In one embodiment, a material of the lower ring 131 may be substantially the same as a material of the upper ring 132. In one embodiment, a material of the lower ring 131 may be different from a material of the upper ring 132. In one embodiment, the lower ring 131 may further include a lower ring third portion 131C between the lower ring first portion 131A and the lower ring second portion 131B, and the lower ring third portion 131C may have a third width W1C greater than the first width W1A and less than the second width W1B. In one embodiment, the ring structure 130 further may include a ring structure corner portion 130-1 located a corner of the semiconductor die module 120, and a ring structure straight portion 130-2 along a side of the semiconductor die module 120. In one embodiment, the lower ring 131 may include a lower ring corner portion 131-1 in the ring structure corner portion 130-1, wherein the lower ring corner portion 131-1 includes the lower ring first portion 131A having the first width W1A and the lower ring second portion 131B having the second width W1B greater than the first width W1A, and a lower ring straight portion 131-2 in the ring structure straight portion 130-2, wherein the lower ring straight portion 131-2 includes the lower ring first portion 131A having the first width W1A and the lower ring second portion 131B having a width substantially equal to the first width W1A. In one embodiment, the upper ring 132 may include an upper ring 132 corner portion in the ring structure corner portion 130-1, wherein the upper corner portion may be attached to the lower ring second portion 131B, and an upper ring 132 straight portion in the ring structure straight portion 130-2 and attached to the lower ring straight portion 131-2. In one embodiment, the lower ring corner portion 131-1 may be integrally formed with the lower ring straight portion 131-2 and the upper ring 132 corner portion may be integrally formed with the upper ring 132 straight portion.

Referring again to FIGS. 1A-11, a method of making a package structure 100 may include mounting a semiconductor die module 120 on a package substrate 110, applying a first adhesive layer 160a to the package substrate 110 around the semiconductor die module 120, attaching a lower ring 131 of a ring structure 130 to the package substrate 110 around the semiconductor die module 120 with the first adhesive layer 160a, wherein the lower ring 131 includes a lower ring first portion 131A having a first width W1A and a lower ring second portion 131B having a second width W1B greater than the first width W1A, applying a second adhesive layer 160b to the lower ring second portion 131B, and attaching an upper ring 132 of the ring structure 130 to the lower ring second portion 131B with the second adhesive layer 160b.

In one embodiment, the ring structure 130 may further include a ring structure corner portion 130-1 located a corner of the semiconductor die module 120, and the attaching of the lower ring 131 may include attaching a lower ring corner portion 131-1 of the ring structure corner portion 130-1 at the corner of the semiconductor die module 120. In one embodiment, the ring structure 130 may further include a ring structure straight portion 130-2 along a side of the semiconductor die module 120, and the attaching of the lower ring 131 may include attaching a lower ring straight portion 131-2 of the ring structure straight portion 130-2 along the side of the semiconductor die module 120. In one embodiment, the attaching of the upper ring 132 to the lower ring second portion 131B may include attaching an upper ring 132 corner portion of the ring structure corner portion 130-1 to the lower ring second portion 131B.

Referring again to FIGS. 1A-11, a package structure 100 may include a package substrate 110, a semiconductor die module 120 on the package substrate 110, a lower ring 131 on the package substrate 110 around the semiconductor die module 120, including a lower ring first portion 131A having a first width W1A, and a lower ring second portion 131B having a second width W1B greater than the first width W1A, and a package lid 150 over the semiconductor die module 120 and attached to the lower ring second portion 131B.

In one embodiment, the package structure 100 may further include a first adhesive layer 160a between the lower ring first portion 131A and the package substrate 110, and a second adhesive layer 160b between the lower ring second portion 131B and the package lid 150. In one embodiment, an outer sidewall of the package lid 150 may be substantially aligned with an outer sidewall of the lower ring 131. In one embodiment, the package structure 100 may further include a thermal interface material (TIM) layer 170 on the semiconductor die module 120, wherein the package lid 150 contacts an upper surface of the TIM layer 170.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a semiconductor die module on the package substrate; and
a ring structure on the package substrate around the semiconductor die module, comprising:
a lower ring including a lower ring first portion having a first width and a lower ring second portion having a second width greater than the first width; and
an upper ring attached to the lower ring second portion.

2. The package structure of claim 1, further comprising:
a first adhesive layer between the lower ring first portion and the package substrate; and
a second adhesive layer between the lower ring second portion and the upper ring.

3. The package structure of claim 1, wherein the upper ring has a width substantially the same as the second width of the lower ring second portion.

4. The package structure of claim 1, wherein the lower ring first portion has a first cross-sectional area and the lower ring second portion has a second cross-sectional area greater than the first cross-sectional area.

5. The package structure of claim 4, wherein the upper ring has a cross-sectional area equal to or greater than the second cross-sectional area of the lower ring second portion.

6. The package structure of claim 1, wherein a material of the lower ring is substantially the same as a material of the upper ring.

7. The package structure of claim 1, wherein a material of the lower ring is different from a material of the upper ring.

8. The package structure of claim 1, wherein the lower ring further includes a lower ring third portion between the lower ring first portion and the lower ring second portion, and the lower ring third portion has a third width greater than the first width and less than the second width.

9. The package structure of claim 1, wherein the ring structure further comprises:
a ring structure corner portion located a corner of the semiconductor die module; and
a ring structure straight portion along a side of the semiconductor die module.

10. The package structure of claim 9, wherein the lower ring comprises:
a lower ring corner portion in the ring structure corner portion, wherein the lower ring corner portion includes the lower ring first portion having the first width and the lower ring second portion having the second width greater than the first width; and
a lower ring straight portion in the ring structure straight portion, wherein the lower ring straight portion includes the lower ring first portion having the first width and the lower ring second portion having a width substantially equal to the first width.

11. The package structure of claim 10, wherein the upper ring comprises:
an upper ring corner portion in the ring structure corner portion, wherein the upper corner portion is attached to the lower ring second portion; and
an upper ring straight portion in the ring structure straight portion and attached to the lower ring straight portion.

12. The package structure of claim 11, wherein the lower ring corner portion is integrally formed with the lower ring straight portion and the upper ring corner portion is integrally formed with the upper ring straight portion.

13. A method of making a package structure, the method comprising:
mounting a semiconductor die module on a package substrate;
applying a first adhesive layer to the package substrate around the semiconductor die module;
attaching a lower ring of a ring structure to the package substrate around the semiconductor die module with the first adhesive layer, wherein the lower ring includes a lower ring first portion having a first width and a lower ring second portion having a second width greater than the first width;
applying a second adhesive layer to the lower ring second portion; and
attaching an upper ring of the ring structure to the lower ring second portion with the second adhesive layer.

14. The method of claim 13, wherein the ring structure further comprises a ring structure corner portion located a corner of the semiconductor die module, and the attaching of the lower ring comprises attaching a lower ring corner portion of the ring structure corner portion at the corner of the semiconductor die module.

15. The method of claim 14, wherein the ring structure further comprises a ring structure straight portion along a side of the semiconductor die module, and the attaching of the lower ring comprises attaching a lower ring straight portion of the ring structure straight portion along the side of the semiconductor die module.

16. The method of claim 14, wherein the attaching of the upper ring to the lower ring second portion comprises attaching an upper ring corner portion of the ring structure corner portion to the lower ring second portion.

17. A package structure, comprising:
a package substrate;
a semiconductor die module on the package substrate;
a lower ring on the package substrate around the semiconductor die module, comprising:
a lower ring first portion having a first width; and
a lower ring second portion having a second width greater than the first width; and
a package lid over the semiconductor die module and attached to the lower ring second portion.

18. The package structure of claim 17, further comprising:
a first adhesive layer between the lower ring first portion and the package substrate; and
a second adhesive layer between the lower ring second portion and the package lid.

19. The package structure of claim 17, wherein an outer sidewall of the package lid is substantially aligned with an outer sidewall of the lower ring.

20. The package structure of claim 17, further comprising:
a thermal interface material (TIM) layer on the semiconductor die module, wherein the package lid contacts an upper surface of the TIM layer.
